(19) United States
(12) Patent Application Publication
(10) Pub. No.: US 2009/0079083 A1
(43) Pub. Date: Mar. 26, 2009

(54) INTERCONNECT STRUCTURE AND FABRICATING METHOD OF THE SAME

(75) Inventor: Chin-Sheng Yang, Hsinchu (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/861,907

(22) Filed: Sep. 26, 2007

(51) Int. Cl. H01L 21/4763; H01L 23/52

(52) U.S. Cl. 257/773; 438/624; 257/E23.141; 257/E21.495

(57) ABSTRACT

A fabricating method of an interconnect structure is provided. A first dielectric layer is formed on a substrate for covering an air gap region and a non-air gap region. Next, interconnects are formed in the first dielectric layer on the air gap region and in the first dielectric layer on the non-air gap region. Then, a cap layer is formed on the first dielectric layer. Thereafter, on the air gap region, a portion of the cap layer and a portion of the first dielectric layer are removed for forming first openings, and thereby a portion of the first dielectric layer are left between the interconnects for forming support pillars. After that, a second dielectric layer is formed over the substrate for covering the cap layer and the first openings, so as to form an air gap in each of the first openings.

### BACKGROUND OF THE INVENTION

1. Field of the Invention

The present invention relates to a semiconductor device and a fabricating method thereof, and in particular, to an interconnect structure and a fabricating method thereof.

2. Description of Related Art

As devices are continuously miniaturized, the operational speed of transistors is increasingly faster; however, a RC delay of interconnects seriously affects the signal processing time. Currently, in order to reduce the RC delay, a dielectric material with a low dielectric constant is adopted to replace silicon dioxide as a dielectric layer. The RC delay can also be reduced by forming air gaps in the dielectric layer.

According to a conventional fabricating method of an interconnect structure, the method for forming air gaps in a dielectric layer usually includes that a dielectric layer is deposited after wire lines of interconnects are formed. The air gaps are formed in gaps because the deposited dielectric layer is not completely filled out the gaps between two adjacent interconnects. On the other hand, a dual damascene process includes filling metal into trenches and via openings in the dielectric layer, and performing a chemical-mechanical polishing process. Next, the dielectric layer between the interconnects is removed to form openings by performing a photolithographic and an etching process. Then, another dielectric layer is additionally deposited in the openings, and air gaps are formed because the additionally deposited dielectric layer cannot completely fill in the openings between the interconnects.

FIG. 1 is a schematic cross-sectional view illustrating a conventional multi-layered interconnect structure having air gaps.

Referring to FIG. 1, in the conventional interconnect structure, usually, in order to reduce a parasitic capacitance of interconnects, air gaps 128 are formed in a dielectric layer 114 between the interconnects 108 in each layer on an area having a higher parasitic capacitance (herein, an air gap region 102), of a substrate 100. However, air gaps are not formed in the dielectric layer 106 between the interconnects 108 on an area (herein, a non-air gap region 152) which has a lower parasitic capacitance or is less affected by a parasitic capacitance delay. In regard to the dual damascene process, a cap material layer is covered on the air gap region 102 and the non-air gap region 152 after the interconnects 108 are formed. Then, a patterned photoresist layer is formed (not shown). The patterned photoresist layer completely covers the cap material layer on the non-air gap region 152 and completely exposes the cap material layer on the air gap region 102. After that, a portion of the cap material layer, which is exposed by the photoresist layer is removed by performing an etching process, and a portion of the cap material layer 110 remains on the non-air gap region 152. Thereafter, by continuously performing the etching process, a portion of the dielectric layer 106 between the interconnects 108 on the region 102 is removed for forming a plurality of openings 112, while the dielectric layer 106 on the non-air gap region 152 is reserved. Then, a dielectric layer 114 is filled in the openings 112. Many air gaps 128 are formed in the openings 112 because the dielectric layer 114 is not completely filled out the openings 112.

Although the parasitic capacitance can be effectively reduced by forming the air gaps 128, because the air gaps 128 are formed between the interconnects in each layer on the air gap region 102, an high opening ratio of the air gaps 128 results in a problem of insufficient mechanical strength of the dielectric layer 114, and therefore the dielectric layer 114 collapses or sinks in a subsequent chemical-mechanical polishing process or a thermal process.

### SUMMARY OF THE INVENTION

The present invention is directed to an interconnect structure which has a great number of air gaps for reducing a parasitic capacitance and provides sufficient mechanical strength at the same time.

The present invention is directed to a fabricating method of an interconnect structure. The fabricating method includes steps as follows. First, a first dielectric layer is formed on a substrate for covering an air gap region and a non-air gap region of the substrate. Next, a plurality of interconnects is formed in the first dielectric layer on the air gap region and in the first dielectric layer on the non-air gap region. Then, a cap layer is formed on the first dielectric layer. After that, a portion of the cap layer and a portion of the first dielectric layer on the air gap region are removed for forming a plurality of first openings, and thereby a portion of the first dielectric layer is left between the interconnects on the air gap region for forming a plurality of support pillars. Thereafter, a second dielectric layer is formed on the substrate for covering the cap layer and the first openings, and thereby an air gap is formed in each of the first openings.

In the aforesaid fabricating method of the interconnect structure according to an embodiment of the present invention, the steps for removing a portion of the cap layer in the air gap region and for removing the portion of the first dielectric layer are described as follows. First, a mask layer which has a plurality of second openings is formed over the substrate. The mask layer covers the cap layer on the non-air gap region and a portion of the cap layer on the air gap region. The second openings expose at least a portion of the cap layer on the air gap region. Next, the portion of the cap layer, which are exposed by the second openings, and the first dielectric layer thereunder are removed to form the first openings. Therefore, the portion of the first dielectric layer, which is left between the interconnects forms support pillars. Then, the mask layer is removed.

In the aforesaid fabricating method of the interconnect structure according to an embodiment of the present invention, an opening ratio of the second openings on the mask layer on the air gap region is about 70%.

In the fabricating method of the interconnect structure according to an embodiment of the present invention, the support pillars are disposed outside areas where vias are formed or predetermined to be formed.

In the fabricating method of the interconnect structure according to an embodiment of the present invention, the interconnects include plurality of wire lines having bends and the support pillars are formed between the bends of wire lines.

In the fabricating method of the interconnect structure according to an embodiment of the present invention, some of the support pillars are formed over an area in which at least one air gap is formed or under an area in which at least one air gap is predetermined to be formed.

In the fabricating method of the interconnect structure according to an embodiment of the present invention, the interconnects include a plurality of wire lines, and a length of the first opening between any pair of adjacent support pillars disposed between any pair of adjacent wire lines is not longer than 3 micrometers.

In the aforesaid fabricating method of the interconnect structure according to an embodiment of the present invention, a material of the first dielectric layer includes silicon oxide, a low dielectric constant material dielectric layer, spin-on-glass, boron phosphorous silicon glass and phosphorous silicon glass.

In the aforesaid fabricating method of the interconnect structure according to an embodiment of the present invention, a material of the cap layer includes silicon nitride (SiN), silicon carbide (SiC), carbon-doped silicon oxide (SiCO), silicon carbon nitride (SiCN), silicon carbo-oxynitride (SiCNO), silicon oxynitride (SiON) or combinations thereof.

In the aforesaid fabricating method of the interconnect structure according to an embodiment of the present invention, a material of the second dielectric layer includes TEOS silicon oxide, undoped silicate glass, boron phosphorous silicon glass, phosphorous silicon glass and fluorin-doped silicon glass.

In the aforesaid fabricating method of the interconnect structure according to an embodiment of the present invention, the air gap region includes a buried device region or a static random access memory region.

The present invention provides an interconnect structure which includes a first dielectric layer, a plurality of interconnects, a plurality of support pillars, a cap layer and a second dielectric layer. The first dielectric layer is disposed on a non-air gap region and an air gap region of a substrate. The interconnects are respectively disposed in the first dielectric layer on the non-air gap region and in the first dielectric layer on the air gap region. A plurality of first openings is formed between any pair of adjacent interconnects on the air gap region. A plurality of support pillars is respectively disposed between any pair of adjacent first openings between each pair of adjacent interconnects on the air gap region. The cap layer covers the first dielectric layer of the non-air gap region, the interconnects, and at least the support pillars of the air gap region. The second dielectric layer covers the cap layer and is filled into the first openings. An air gap is formed in the second dielectric layer in each of the first openings.

According to an embodiment of the present invention, the aforesaid interconnect structure further includes a plurality of protection pillars disposed around a plurality of wire lines which is connected on or under a plurality of vias of the interconnects on the air gap region.

In the interconnect structure of the present embodiment, a material of the support pillars are the same as that of the first dielectric layer and that of the protection pillars.

In the interconnect structure according to an embodiment -of the present invention, a material of the support pillars is the same as that of the first dielectric layer.

In the interconnect structure according to an embodiment of the present invention, the support pillars are formed between the bends of a plurality of wire lines of the interconnects, wherein the wire lines have the bends.

In the interconnect structure according to an embodiment of the present invention, some of the support pillars are formed over areas where at least one air gap is formed or under areas where is predetermined to form at least one air gap.

In the interconnect structure according to an embodiment of the present invention, the interconnect structure includes, from the bottom to the top, a plurality of first wire lines, a plurality of second wire lines, and a plurality of third wire lines. The support pillars are respectively formed over an area which has an air gap disposed between two adjacent second wire lines, and has an air gap region disposed between two adjacent first wire lines.

In the interconnect structure according to an embodiment of the present invention, the interconnects have a plurality of wire lines, and a length of the first opening between any pair of adjacent support pillars disposed between each pair of adjacent wire lines is not greater than 3 micrometers.

In the aforesaid interconnect structure according to an embodiment of the present invention, the air gap region includes a buried device region or a static random access memory region.

The interconnect structure of the present invention has a great number of air gaps for reducing the parasitic capacitances and can provide sufficient mechanical strength at the same time.

The fabricating method of the interconnect structure of the present invention can enhance the mechanical strength without additional steps.

In order to the make the aforementioned and other objects, features and advantages of the present invention more comprehensible, several embodiments accompanied with figures are described in detail below.

### BRIEF DESCRIPTION OF THE DRAWINGS

FIG. 1 is a schematic cross-sectional view illustrating a conventional interconnect structure having air gaps.

FIG. 2 is a schematic cross-sectional view illustrating an interconnect structure having the air gaps according to an embodiment of the present invention.

FIG. 3 is a schematic cross-sectional view illustrating another interconnect structure having the air gaps according to an embodiment of the present invention.

FIGS. 4 through 7 are top views of several interconnect structures having support pillars according to various embodiments of the present invention.

FIGS. 8A through 8C are cross-sectional views illustrating a processing flow for fabricating the interconnect structure according to an embodiment of the present invention.

FIGS. 9 through 14 are top views of several kinds of mask layers according to various embodiments of the present invention.

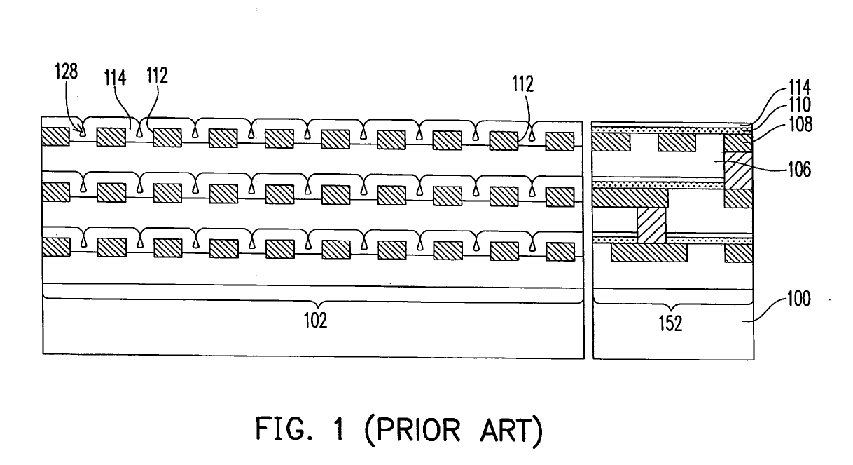

### DESCRIPTION OF EMBODIMENTS

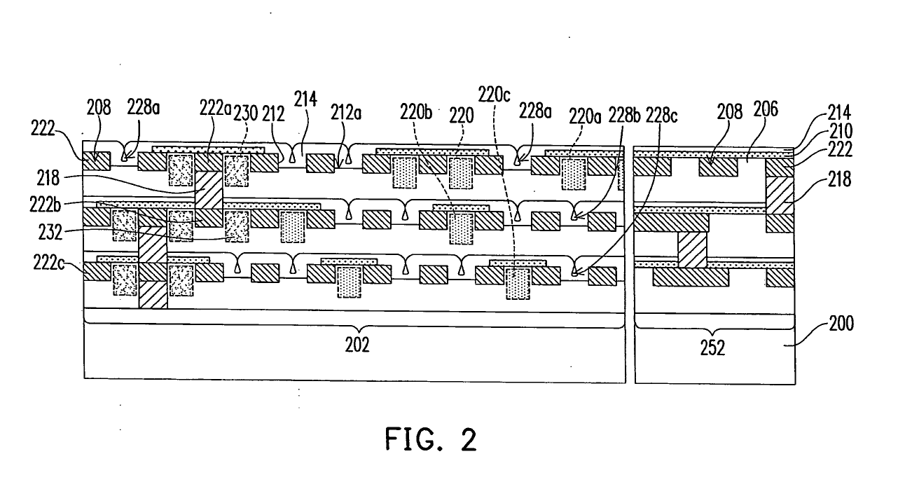

FIG. 2 is a schematic cross-sectional view illustrating an interconnect structure having air gaps according to an embodiment of the present invention.

Referring to FIG. 2, in the present embodiment, the interconnect structure is formed on a substrate 200. The substrate 200 includes an air gap region 202 and a non-air gap region 252. The air gap region 202 is, for example, a region which can lower a parasitic resistance significantly by forming a great number of air gaps, such as a buried device region or a static random access memory region. The non-air gap region 252 is a region outside the air gap region 202, for example, a region having a lower parasitic resistance, or less effected by a parasitic resistance delay.

The dielectric layer 206 on the non-air gap region 252 has a plurality of interconnects 208. The dielectric layer 206 between the interconnects 208 has no air gaps. The interconnects 208 and the dielectric layer 206 are covered by a cap layer 210. A material of the dielectric layer 206 can be an organic material or an inorganic material, such as tetraethylorthosilicate (TEOS) silicon oxide, undoped silicate glass (USG), boron phosphorous silicon glass (BPSG), phosphorous silicon glass (PSG), a low dielectric constant material, or combinations thereof The low dielectric constant material is a material layer with a dielectric constant less than 4, for example, fluorin-doped silicon glass (FSG); silsesquioxnane, such as hydrogen silsesquioxane (HSQ), methyl silsesquioxane (MSQ), and hybrido-organo siloxane polymer (HOSP); aromatic hydrocarbon, such as SiLK; organosilicate glass, such as black diamond (BD), 3MS and 4MS; parylene; fluoro-polymer, such as PFCB, CYTOP and Teflon; Poly (arylethers), such as PAE-2 and FLARE; porous polymer, such as XLK, Nanofoam and Awrogel; Coral and the like. The cap layer 210 is covered by a dielectric layer 214. A material of the cap layer 210 includes, for example, silicon nitride (SiN), silicon carbide (SiC), carbon-doped silicon oxide (SiCO), silicon carbon nitride (SiCN), silicon carbo-oxynitride, silicon oxynitride (SiON), and combinations thereof. The cap layer 210 is covered by the dielectric layer 214. A material of the dielectric layer 214 can be the same as or different from that of the dielectric layer 206. A material of the dielectric layer 214 includes an organic material or an inorganic material, such as TEOS silicon oxide, USG, BPSG, PSG or FSG.

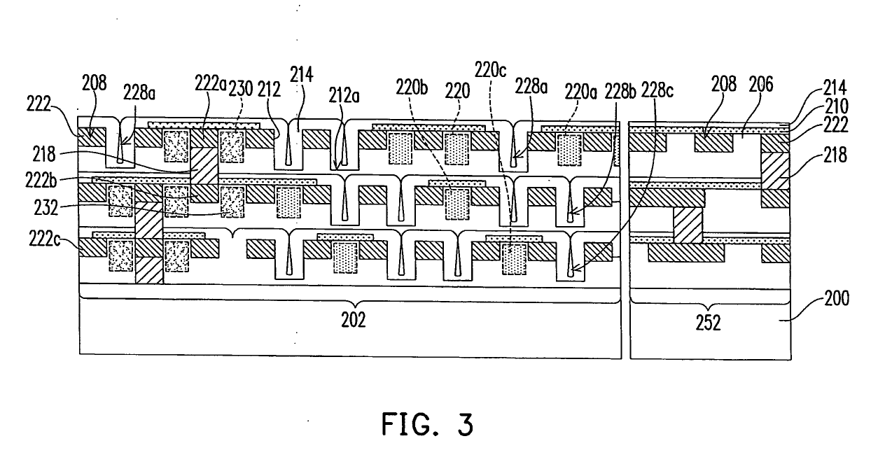

A plurality of interconnects 208 is disposed on the air gap region 202. Some of the interconnects 208 are completely covered by the cap layer 210; some of the interconnects 208 are not covered or partially covered by the cap layer 210. Openings 212 are formed in an area not covered by the cap layer 210 between the interconnects 208. A bottom surface 212a of the opening 212 can be disposed between each pair of wire lines 222 of any pair of adjacent interconnects 208 (as shown in FIG. 2), or can be disposed downward to the level of contacts 218 which are under wire lines 222 (as shown in FIG. 3). A dielectric layer 214 is filled in the openings 212. An air gap 228 is formed in each of the openings 212 because the dielectric layer 214 does not completely fill out the openings 212. The air gaps 228 have a low dielectric constant for lowering a dielectric constant of the entire dielectric layer. The material of the dielectric layer 214 can be the same as or different from that of the dielectric layer 206. The material of the dielectric layer 214 includes an organic material or an inorganic material, such as TEOS silicon oxide, USG, BPSG, PSG or FSG.

The openings 212 are not formed in an area covered by the cap layer 210 between the interconnects 208 on the air gap region 202; dummy pillars are disposed therein. The dummy pillars include support pillars 220 and protection pillars 230 or 232. The support pillars 220 and protection pillars 230 or 232 are used for different purposes and have different effects. The protection pillars 230 or 232 are disposed in connection with the vias 218. In order to prevent a misalignment, which occurs during the formation of the via openings, from causing a short circuit problem because a metallic layer supposed to be filled in via openings fills in the air gaps around the via openings mistakenly, the protection pillars 232 are formed around the wire lines 222b of the interconnects 208, which are connected under an area where the vias 218 are predetermined to be formed, so as to prevent the air gaps from being formed mistakenly. The protection pillars 230 are also formed around the wire lines 222a of the interconnects 208, which are connected on an area where the vias 218 are formed, so as to prevent air gaps from being formed mistakenly. The disposition of the support pillars 220 is irrelevant to the vias 218. The support pillars 220 are disposed to solve the problem of insufficient mechanical strength which is derived from too many air gaps 228 being formed on the air gap region 202. The support pillars 220 are disposed for enhancing the mechanical strength of the dielectric layer on the air gap region 202, thereby preventing the dielectric layer from collapsing or sinking. A material of the support pillars 220 can be the same as or different from that of the protection pillars 230 or 232. In an embodiment, the material of the support pillars 220 and the protection pillars 230 or 232 are the same as that of the dielectric layer 206, such as TEOS silicon oxide, USG, BPSG, PSG, a low dielectric constant material, and combinations thereof The low dielectric constant material is the material layer with a dielectric constant less than 4, such as FSG; silsesquioxnane, such as HSQ, MSQ, and HOSP; aromatic hydrocarbon, such as SiLK; the organosilicate glass, for example, BD, 3MS and 4MS; parylene; fluoro-polymer, such as PFCB, CYTOP, and teflon; Poly (arylethers), such as PAE-2 and FLARE; porous polymer, such as XLK, nanofoam and Awrogel; Coral and the like.

The support pillars 220 are disposed on the premise that the disposition can enhance the mechanical strength or provide the sufficient mechanical strength. The number of the support pillars 220 can vary with the required mechanical strength per unit area or per unit volume. In an embodiment, in a vertical direction perpendicular to an upper surface of the substrate 200, at least one support pillar 220 is disposed over or under two adjacent air gaps 228. Referring to FIG. 2, each of the interconnects 208 includes, from the bottom to the top, first wire lines 222c, second wire lines 222b and third wire lines 222a. Support pillars 220a are respectively formed between two adjacent third wire lines 222a, wherein an air gap 228b is formed between two adjacent second wire lines 222b under the support pillars 220a, and an air gap 228c is also formed between two adjacent first wire lines 222c under the support pillar 222a. Support pillars 220c are respectively formed between two adjacent first wire lines 222c, wherein an air gap 228b is formed between two adjacent second wire lines 222b over the support pillar 220c, and an air gap 228a is formed between two adjacent third wire lines 222a over the support pillars 220c. Support pillars 220b are respectively formed between two adjacent second wire lines 222b, wherein an air gap 228c is formed between two adjacent first wire lines 222c under the support pillar 220b, and an air gap 228a is also predetermined to be formed between two adjacent third wire lines 222a over the support pillar 220b.

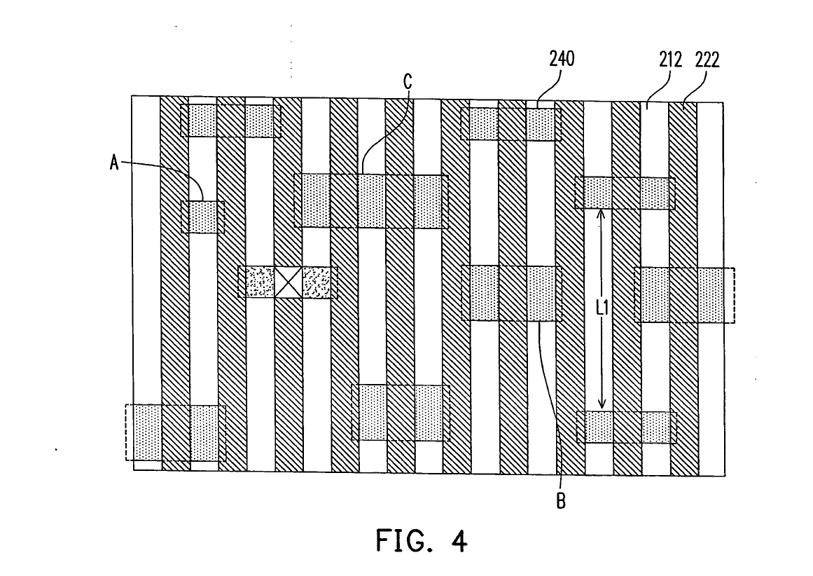

FIGS. 4 through 7 are top views of several kinds of the interconnect structures having support pillars according to embodiments of the present invention.

Referring to FIG. 4, sizes of the support pillars 220 on the air gap region 202 can be the same as or different from one another. For example, the support pillar 220 with a bigger cross-section can be used in a fragile area for providing sufficient mechanical strength. Each of the support pillars 220 can be isolated between any pair of adjacent interconnects 208, as shown by A zone. A support group 240 can be formed by a plurality of support pillars 220 which is disposed between a plurality of interconnects 208. For example, the support group 240 can be a support group B composed of two support pillars 220, or a support group C composed of three support pillars 220, or a larger support group composed of more support pillars 220.

In an embodiment, in order to provide sufficient mechanical strength, in a same layer along a direction parallel to the upper surface of the substrate 200, a distance L between any pair of adjacent support pillars 220 which are disposed between any pair of adjacent interconnects 208 is not longer than 3 micrometers. Shapes of the support pillars 220 or the support groups 240 on the air gap region 202 are not specified. The shapes of the support pillars 220 or the support groups 240 can be a rectangle, a circle, an ellipse, a rhombus, a polygon, or other shapes. Besides, the shape of each support pillar 220 can be the same as or different from that of each support group 240.

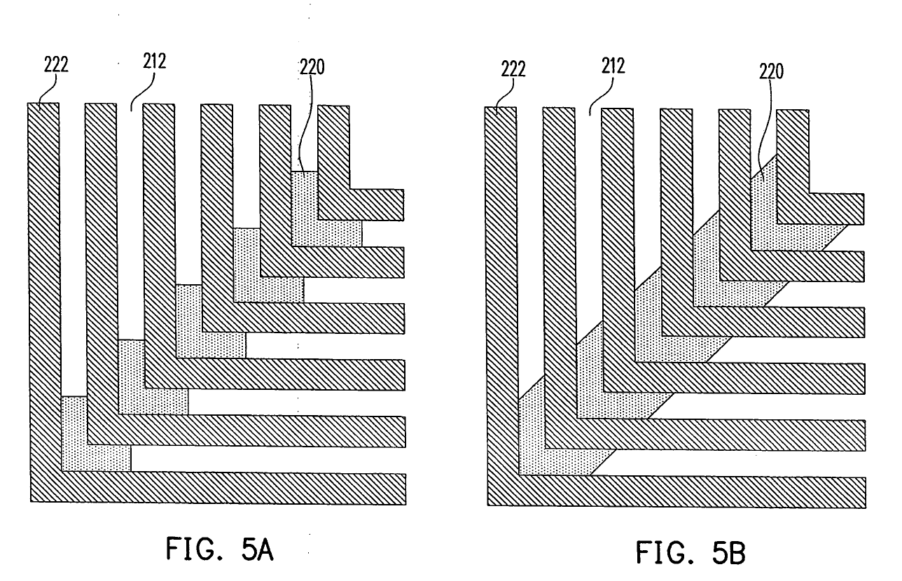

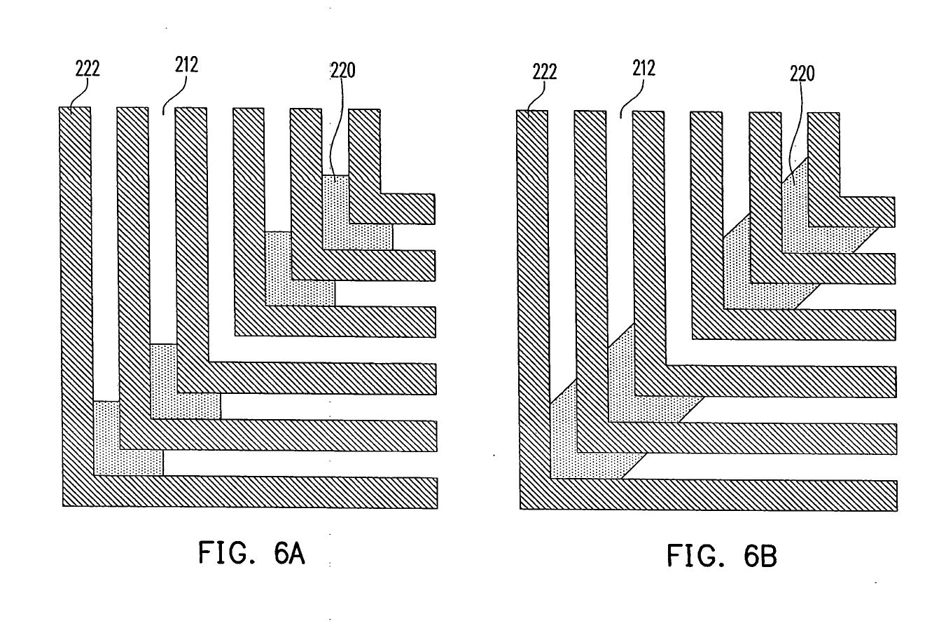

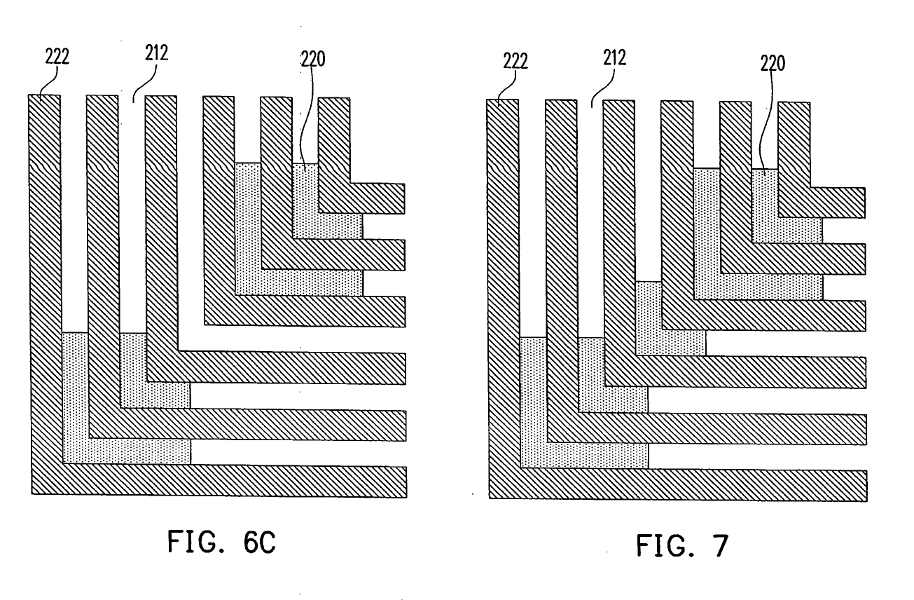

Referring to FIGS. 5A through 7, when performing a chemical-mechanical polishing process, some areas in the interconnect structures are relatively fragile, for example, the interconnects having corners or bends are extremely fragile at corners or the bends. The support pillars 220 can be disposed in the fragile areas, for example, between the bends of the wire lines 222. In an embodiment, support pillars 220 are respectively disposed between the bends of any pair of adjacent wire lines 222, as shown in FIG. 5A, FIG. 5B and FIG. 7. In another embodiment, not between all of the bends of any pair of wire lines 222 are disposed the support pillar 220. The support pillar 220 is only disposed between the bends of some wire lines 222, as shown in FIG. 6A, FIG. 6B and FIG. 6C. The sizes of the support pillars 220 respectively disposed between the bends of any pair of wire lines 222 can be the same as (as shown in FIGS. 5A, 5B and 6A and 6B) or different (as shown in FIG. 6C and FIG. 7) from one another. Furthermore, the shapes of the support pillars 220 respectively disposed between the bends of the wire lines are not limited and can be the same or different from one another.

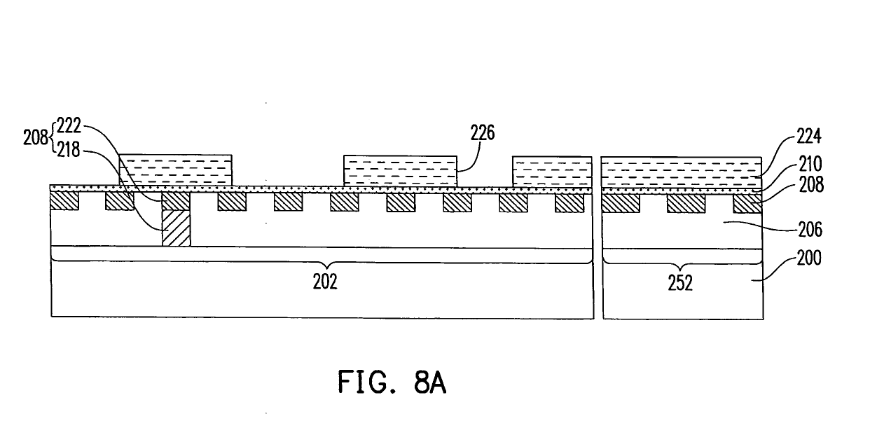

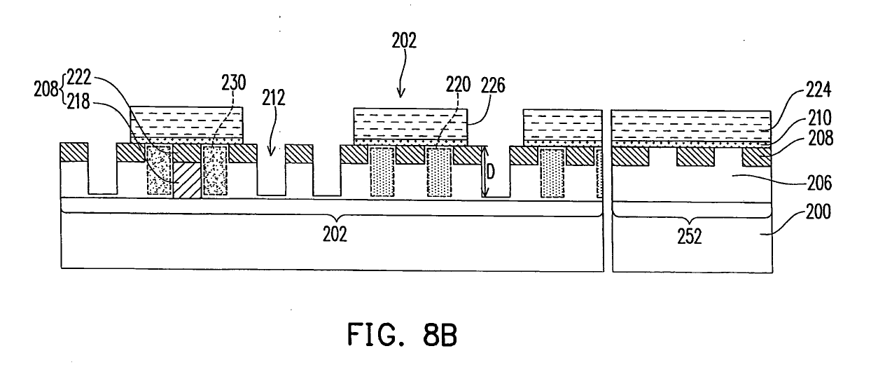

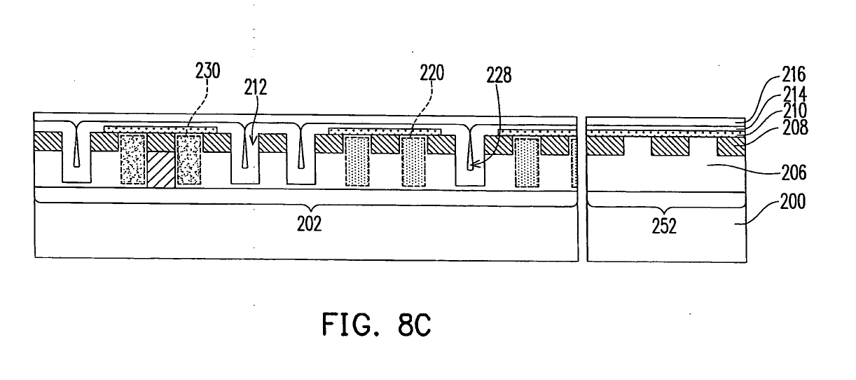

FIGS. 8A through 8C are cross-sectional views illustrating a processing flow for fabricating an interconnect structure according to an embodiment of the present invention.

Referring to FIG. 8A, a substrate 200 is provided. The substrate 200 is, for example, a semiconductor substrate made of silicon, or a semiconductor compound substrate such as SiGe substrate, or silicon-on-insulator (SOI). On the substrate 200, a semiconductor device (not shown) or an interconnect (not shown) have already been formed, for example. The substrate 200 includes an air gap region 202 and a non-air gap region 252. The air gap region 202 is, for example, a buried device region or a static random access memory region which reduces a parasitic resistance significantly by forming a great number of air gaps. The non-air gap region 252 is a region outside the air gap region 202. The non-air gap region 252 is, for example, a region which has less parasitic resistance or is less affected by a parasitic resistance delay.

Next, a dielectric layer 206 is formed to cover the air gap region 202 and the non-air gap region 252 of the substrate 200. A material of the dielectric layer 206 includes an organic material or an inorganic material. The material can be, for example, TEOS silicon oxide, USG, BPSG, PSG, a low dielectric constant material, and combinations thereof The low dielectric constant material is a material layer with a dielectric constant less than 4, such as FSG; silsesquioxnane, such as HSQ, MSQ, and HOSP; aromatic hydrocarbon, such as SiLK; organosilicate glass, such as BD, 3MS and 4MS; parylene; fluoro-polymer, such as PFCB, CYTOP and Teflon; Poly (arylethers), such as PAE-2 and FLARE; porous polymer, such as XLK, Nanofoam and Awrogel; Coral and the like. A method for forming the dielectric layer 206 includes a plasma-enhanced chemical vapor deposition (PECVD) process, a sub-atmosphere chemical vapor deposition process, a high-temperature thermal oxidation process, a low-pressure chemical vapor deposition (LPCVD) process, a high density plasma chemical vapor deposition (HDPCVD) process and so forth.

Then, interconnects 208 are respectively formed in the dielectric layer 206 of the air gap region 202 and in the dielectric layer 206 of the non air gap region 252. The interconnects 208 can be formed by performing a dual damascene process. The dual damascene process includes, for example, steps as follows. Trenches and via openings (not shown) are formed in the dielectric layer 206 at first. Next, a conductive material is filled into the trenches and the via openings by performing a deposition process and a chemical-mechanical polishing process to form wire lines 222 and vias 218. The conductive material is, for example, copper, aluminum-copper alloy or copper-aluminum-silicon alloy. Then, a cap layer 210 is formed over the substrate 200. A material of the cap layer 210 is, for example, SiN, SiC, SiCO, SiCN, SiCNO, SiON and combinations thereof. A method for forming the cap layer 210 includes, for example, the high-temperature thermal oxidation process, the plasma-enhanced chemical vapor deposition process, the sub-atmosphere chemical vapor deposition process, the low-pressure chemical vapor deposition process and so forth. Thereafter, a mask layer 224 is formed on the cap layer 210. The mask layer 224 is, for example, a patterned photoresist layer.

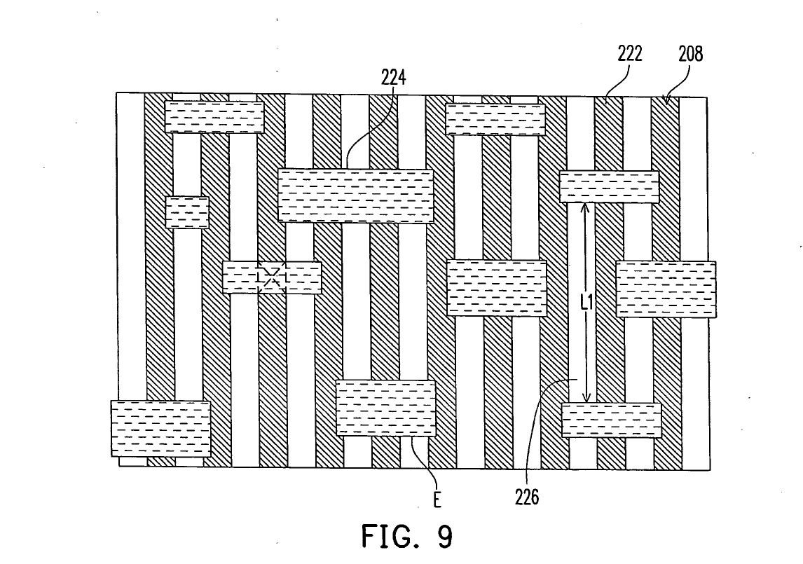

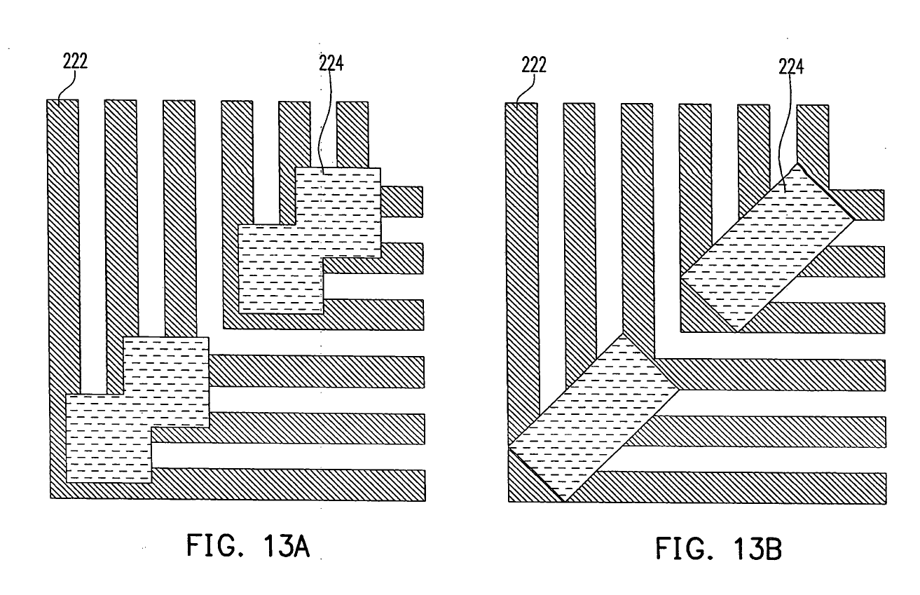

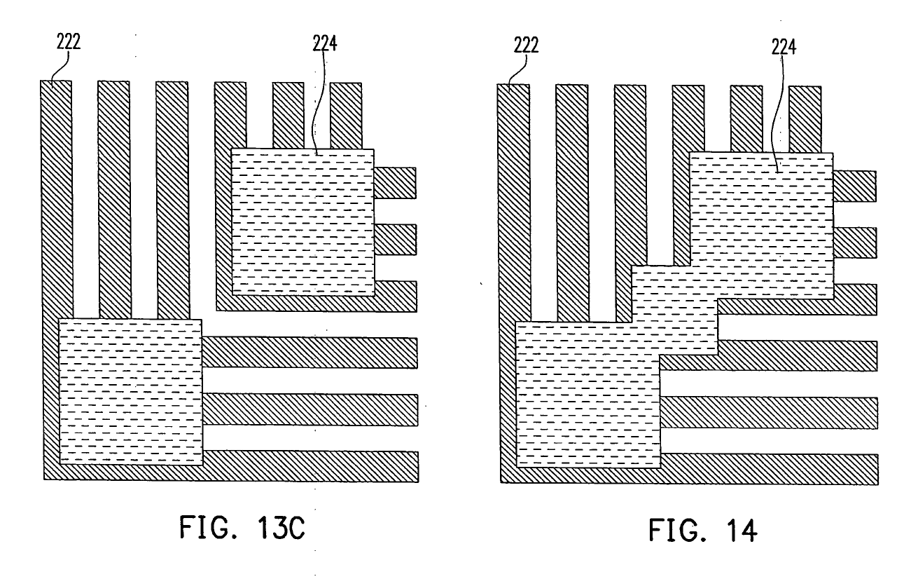

The mask layer 224 on the non-air gap 252 completely covers the cap layer 210. The mask layer 224 on the air gap region 202 has a plurality of openings 226. The mask layer 224 on the air gap region 202 covers at least an area where support pillars and protection pillars are predetermined to be formed therein. The openings 226 of the mask layer 224 on the air gap region 202 expose at least an area where is predetermined for forming air gaps. In an embodiment, an opening ratio of the openings 226 of the mask layer 224 on the air gap region 202 is about 70%. A length L1 of each opening 226 between two adjacent mask layers 224 which are disposed between two adjacent interconnects 208 is not longer than 3 micrometers (as shown in FIG. 9). The shapes and sizes of the mask layer 224 on the air gap region 202 can vary with the actual demands. FIGS. 9 through 14 are several schematic views illustrating several kinds of the mask layers 224 on the air gap region 202. For a clearer explanation, the cap layer 210 is not shown in these drawings.

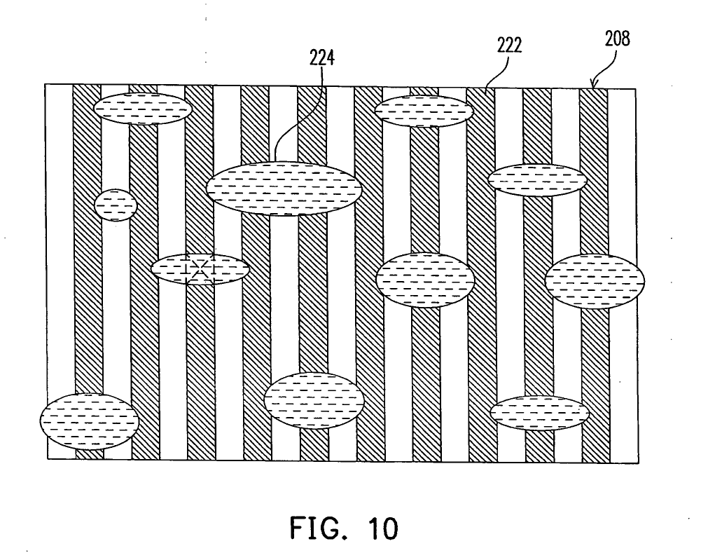

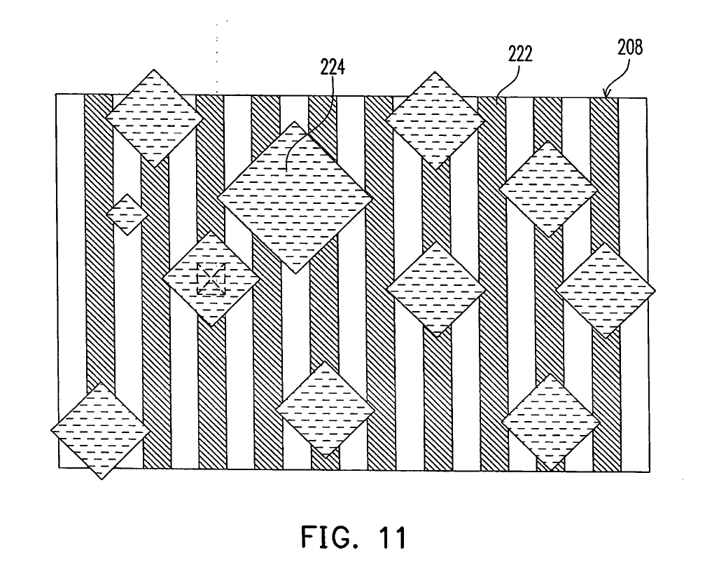

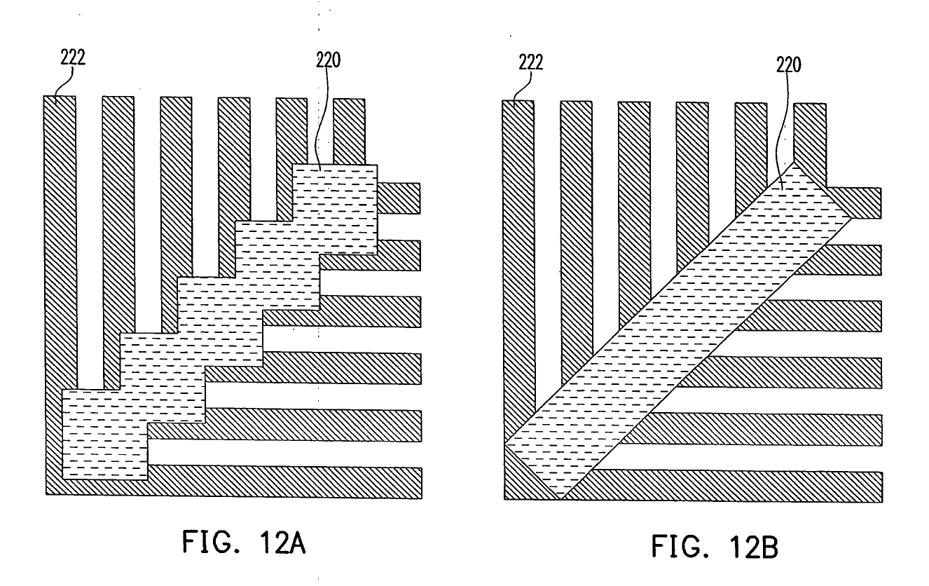

Referring to FIG. 9, each portion of the mask layer 224 covers at least an area predetermined for forming the support pillars and the protection pillars. In the area predetermined for forming the support pillars, the mask layer 224 can cover the area which is predetermined for forming the support pillars, and the interconnects 208 between the support pillars so as to form a larger area, an area E, for example. The shape of the mask layer 224 on the air gap region 202 has no particular limitations. The shape of the mask layer 224 can be a rectangle (as FIG. 9), a circle (as FIG. 10), an ellipse (as FIG. 10), a rhombus (as FIG. 11) or any other shape. The shapes of the portion of the mask layer 224 on the air gap region 202 can be the same as or different from one another. In accordance with the various shapes of the support pillars shown in FIGS. 5A, 5B, 6A, 6B, 6C and 7, the mask layer 224 can also be respectively designed as shown in FIGS. 12A, 12B, 13A, 13B, 13C and 14.

Thereafter, please refer to FIG. 8B. The cap layer 210 not covered by the mask layer 224 is removed. A method for removing the cap layer 210 can include an anisotropic etching process, for example, a plasma etching process. After that, the dielectric layer 206 exposed by the openings 226 is removed for forming a plurality of openings 212 respectively disposed between two adjacent interconnects 208, while the dielectric layer 206 remaining on the air gap region 202 and covered by the cap layer 210 serves as support pillars 220 or protection pillars 230. The support pillars 220 are used for enhancing the mechanical strength. The protection pillars 230 are disposed around the vias 218. A depth D of the openings 212 can be adjusted according to actual demands and has no particular limitations.

Afterwards, referring to FIG. 8C, the mask layer 224 is removed. Then, a dielectric layer 214 is formed over the substrate 200 for covering the cap layer 210 and the openings 212. The dielectric layer 214 does not completely fill out the openings 212. Therefore, an air gap 228 is formed in each of the openings 212. A material of the dielectric layer 214 can be the same as or different to that of the dielectric layer 206. The material of the dielectric layer 214 includes an organic material or an inorganic material, such as TEOS silicon oxide, USG, BPSG, PSG and FSG. A method for forming the dielectric layer 214 includes the plasma-enhanced chemical vapor deposition process, the sub-atmosphere chemical vapor deposition process, the high-temperature thermal oxidation process, the low-pressure chemical vapor deposition process, the HDPCVD process, and so forth. When the depth D of the opening 212 is deeper, the air gap 228 formed is bigger. When the depth D of the opening 212 is shallower, the air gap 228 formed is smaller. Then, another dielectric layer 216 is formed on the dielectric layer 214. The material of the dielectric layer 216 can be the same as or different from that of the dielectric layers 214 and 206. The material of the dielectric layer 216 includes an organic material or an inorganic material, such as TEOS silicon oxide, USG, BPSG, PSG, the low dielectric constant material, or combinations thereof. The low dielectric constant material layer is the material layer with the dielectric constant less than 4, for example, FSG; silsesquioxnane, such as HSQ, MSQ, and HOSP; aromatic hydrocarbon, such as SiLK; organosilicate glass, such as BD, 3MS and 4MS; parylene; fluoro-polymer, such as PFCB, CYTOP and Teflon; Poly (arylethers), such as PAE-2 and FLARE; porous polymer, such as XLK, Nanofoam and Awrogel; Coral, and the like. A method for forming the dielectric layer 216 includes the plasma-enhanced chemical vapor deposition process, the sub-atmosphere chemical vapor deposition process, the high-temperature thermal oxidation process, the low-pressure chemical vapor deposition process, the HDPCVD process and so forth.

In the present invention, a great number of air gaps are formed on the air gap region and the support pillars are also disposed thereon, and thereby the resistance capacitor (RC) delay is reduced and the mechanical strength is improved.

The present invention can form support pillars by simply modifying the patterns of the mask layer without adding additional steps.

Although the invention has been described with reference to the above embodiments, it will be apparent to one of ordinary skill in the art that modifications to the described embodiment may be made without departing from the spirit of the invention. Accordingly, the scope of the invention will be defined by the attached claims not by the above detailed description.

What is claimed is:

1. A fabricating method of an interconnect structure, comprising:
forming a first dielectric layer on a substrate to cover an air gap region and a non-air gap region of the substrate;
forming a plurality of interconnects in the first dielectric layer on the air gap region and in the first dielectric layer on the non-air gap region;
forming a cap layer on the first dielectric layer;
removing a portion of the cap layer and a portion of the first dielectric layer on the air gap region to form a plurality of first openings, thereby leaving a portion of the first dielectric layer between the interconnects on the air gap region for forming a plurality of support pillars; and
forming a second dielectric layer on the substrate to cover the cap layer and the first openings, wherein an air gap is formed in each of the first openings.

2. The fabricating method of the interconnect structure according to claim 1, wherein steps for removing the portion of the cap layer and the portion of the first dielectric layer in the air gap region comprise:
forming a mask layer over the substrate, the mask layer having a plurality of second openings, the mask layer covering the cap layer on the non-air gap region and a portion of on the air gap region, the second openings exposing at least a portion of the cap layer on the air gap region;
removing the portion of the cap layer exposed by the second openings, and the first dielectric layer thereunder by using the mask layer as a mask to form the first openings, thereby forming the support pillars by the first dielectric layer remaining between the interconnects on the air gap region; and
removing the mask layer.

3. The fabricating method of the interconnect structure according to claim 2, wherein an opening ratio of the second openings of the mask layer over the air gap region is 70%.

4. The fabricating method of the interconnect structure according to claim 1, wherein the support pillars are formed outside areas in which vias are formed or predetermined to be formed.

5. The fabricating method of the interconnect structure according to claim 4, wherein the interconnects include a plurality of wire lines having bends and the support pillars are formed between the bends of wire lines.

6. The fabricating method of the interconnect structure according to claim 4, wherein some of the support pillars are formed over an area in which at least one air gap is formed or under an area in which at least one air gap is predetermined to be formed.

7. The fabricating method of the interconnect structure according to claim 1, wherein the interconnects include a plurality of wire lines, and a length of the first opening between any pair of adjacent support pillars which are disposed between any pair of adjacent wire lines is not longer than 3 micrometers.

8. The fabricating method of the interconnect structure according to claim 1, wherein a material of the first dielectric layer comprises silicon oxide, a low dielectric constant dielectric layer, spin-on-glass, boron phosphorous silicon glass and phosphorous silicon glass.

9. The fabricating method of the interconnect structure according to claim 1, wherein a material of the cap layer comprises silicon nitride (SiN), silicon carbide(SiC), carbon-doped silicon oxide (SiCO), silicon carbon nitride (SiCN), silicon carbo-oxynitride, silicon oxynitride (SiON) and combinations thereof.

10. The fabricating method of the interconnect structure according to claim 1, wherein a material of the second dielectric layer comprises TEOS silicon oxide, undoped silicate glass, boron phosphorous silicon glass, phosphorous silicon glass and fluorin-doped silicon glass.

11. The fabricating method of the interconnect structure according to claim 1, wherein the air gap region comprises a buried device region or a static random access memory region.

12. An interconnect structure, comprising:
a first dielectric layer disposed on a non-air gap region and an air gap region of a substrate;
a plurality of interconnects respectively disposed in the first dielectric layer on the non-air gap region and in the first dielectric layer on the air gap region, a plurality of first openings being respectively formed between any pair of adjacent interconnects on the air gap region;
a plurality of support pillars disposed between any pair of first openings which are disposed between any pair of adjacent interconnects on the air gap region;
a cap layer covering the first dielectric layer of the non-air gap region, the interconnects, and at least the support pillars of the air gap region; and
a second dielectric layer covering the cap layer and filled into the first openings, each of the first openings having an air gap formed in the second dielectric layer.

13. The interconnect structure according to claim 12, wherein the support pillars are disposed outside areas where vias are formed or are predetermined to be formed.

14. The interconnect structure according to claim 12, further comprising a plurality of protection pillars disposed around a plurality of wire lines connected on or under a plurality of vias of the interconnects on the air gap region.

15. The interconnect structure according to claim 14, wherein a material of the support pillars is the same as that of the first dielectric layer and that of the protection pillars.

16. The interconnect structure according to claim 12, wherein a material of the support pillars is the same as that of the first dielectric layer.

17. The interconnect structure according to claim 12, wherein the interconnects include a plurality of wire lines having bends and the support pillars are disposed between the bends of the wire lines of the interconnects.

18. The interconnect structure according to claim 12, wherein some of the support pillars are respectively formed over an area in which at least one air gap is formed or under an area in which at least one air gap is predetermined to be formed.

19. The interconnect structure according to claim 12, wherein the interconnects comprise, from the bottom to the top, a plurality of first wire lines, a plurality of second wire lines, and a plurality of third wire lines; the support pillars being formed over an area in which the air gaps are respectively disposed between the second wire lines and also between the first wire lines.

20. The interconnect structure according to claim 12, wherein the interconnects have a plurality of wire lines, and a length of the first opening between any pair of adjacent support pillars which are disposed between any pair of adjacent wire lines is not longer than 3 micrometers.

21. The fabricating method of the interconnect structure according to claim 12, wherein the air gap region comprises a buried device region or a static random access memory region.
